(19) United States
(12) Patent Application Publication
(10) Pub. No.: US 2019/0035612 A1
(43) Pub. Date: Jan. 31, 2019

(54) SPUTTERING TARGET WITH MICRO CHANNELS

(71) Applicants: SURANJAN DABARE, KOHUWULA (LK); RAVI THIRUN, MARKHAM (CA); GAYAN ARAVINDA ABEYGUNAWARDANE, PALLENWATTE (LK); ROMMEL MONTES, CALGARY (CA)

(72) Inventors: SURANJAN DABARE, KOHUWULA (LK); RAVI THIRUN, MARKHAM (CA); GAYAN ARAVINDA ABEYGUNAWARDANE, PALLENWATTE (LK); ROMMEL MONTES, CALGARY (CA)

(21) Appl. No.: 15/660,198

(22) Filed: Jul. 26, 2017

(51) Int. Cl. H01J 37/34; C23C 14/35; C23C 14/34

(52) U.S. Cl. CPC H01J 37/3435; H01J 37/3497; H01J 37/345; C23C 14/3407; H01J 37/3414; C23C 14/35

(57) ABSTRACT

A sputtering target comprises a target material bonded to a backing plate. The target material has a circular disk shape and comprises a sputtering material. The backing plate has a circular disk shape and comprising an external surface. The external surface comprises a plurality of micro channels inset within that span the external surface. The sputtering target is arranged in a sputtering reactor with the external surface of the backing plate disposed external to the sputtering reactor and facing a magnetron, a nano fluid is introduced onto the external surface between the magnetron and the sputtering target, thereby cooling the sputtering target.

### FIELD OF THE INVENTION

The present invention relates to chemical vapor deposition (CVD) and more particularly to the use of sputtering targets in CVD processes.

### DESCRIPTION OF RELATED ART

Semiconductor integrated circuits typically include multiple levels of metallization to provide electrical connections between large numbers of active semiconductor devices. The deposition of the layer or the metallization is typically done by conventional vapour deposition, also called sputtering. A magnetron sputtering reactor is powered by an electrical source and has a target which is composed of a solid target of the material to be sputter deposited bonded to a target backing plate. The magnetron is scanned about the back surface of the target backing plate and projects its magnetic field into the portion of the reactor adjacent the target to increase the plasma density there to thereby increase the sputtering rate.

A simplified example of such a reactor is illustrated in FIG. 1. The reactor includes a vacuum chamber 101, usually of metal and electrically grounded, sealed through a target isolator to a target 100 having at least a target material portion composed of the material to be sputtered on a wafer 103. The wafer may be different sizes including 150, 200, 300 and 450 mm. The wafer may be composed of silicon, glass, or other materials. The wafer 103 is supported by a support surface of an RF pedestal electrode 102 which capacitively couples RF energy into the interior of the reactor. The target 100 provides a second electrode facing the pedestal electrode 102 for capacitive coupling. The RF energy provided by the pedestal 102 ionizes a precursor gas such as argon to maintain a plasma in the area between the electrodes to ionize sputtered deposition material to improve bottom coverage. Above the chamber 101 there is a magnetron 104 positioned above the target 100, that will create the plasma.

During the sputtering process, the temperature of the target needs to be controlled to achieve even and uniform vapour deposition. Target backing plate cooling is essential in this regard to maintain a constant temperature of the target. Current cooling techniques used have a spiral shape cooling line that has semi-circle cross sections on the exterior surface of the target backing plate. A cooling liquid is introduced at the centre of the back plate and flows to the outer edge of the target. Since the coolant enters from the centre, the temperature is at its minimum at that point. However, as it flows through the grooves the coolant gets heated along the way and increases in temperature the further it travels from the centre. This causes the temperature difference between the heated back plate and the coolant to be low and the heat transfer to be lower as the coolant flow away from the centre which causes non uniform cooling throughout the back plate.

Furthermore, the grooves are oriented in such a way that they obstruct the coolant flow. This causes the coolant to stay and rotate within the same volume and hence the heat transfer will be even less uniform.

Complicating matters, the space between the magnetron 104 and the exterior surface of the target backing plate 100 may be as small as 1.5 mm. Any cooling technique must operate within this space which constrains techniques that may solve this problem efficiently.

Other aspects and features of the present invention will become apparent to those ordinarily skilled in the art upon review of the following description of specific embodiments of the invention in conjunction with the accompanying figures.

### BRIEF SUMMARY OF THE INVENTION

In embodiments of the invention, a sputtering target comprises a target material. The target material is a circular disk and comprises a sputtering material. The sputtering target also comprises a backing plate bonded to the target material. The backing plate has a circular disk shape and comprises an external surface. The external surface comprises a plurality of micro channels inset within. The plurality of micro channels span the external surface.

In some embodiments, the plurality of micro channels are arranged in parallel. In other embodiments the plurality of micro channels extend radially from the centre of the external surface.

In some embodiments, the plurality of micro channels have a rectangular cross section. The plurality of micro channels have a width and a depth, the ratio of width to depth being between 1:5 and 1:15. In other embodiments the bottom portion of the plurality of micro channels have a circular cross section. In further embodiments the bottom portion of the plurality of micro channels have a triangular cross section.

Other embodiments of the invention include a method of cooling a sputtering target. A sputtering target is arranged in a sputtering reactor. The sputtering target comprises a target material bonded to a backing plate. An external surface of the backing plate is disposed external to the sputtering reactor and facing a magnetron. A nano fluid is introduced onto the external surface between the magnetron and the sputtering target.

In some embodiments the nano fluid comprises a plurality of particles smaller than 100 nm in mean diameter.

In some embodiments the plurality of particles are comprised of aluminum oxide.

In some embodiments the plurality of particles comprise between 3% and 5% concentration of the nano fluid.

In further embodiments of the method, the external surface comprises a plurality of micro channels inset within and the plurality of micro channels spanning the external surface. In some embodiments the plurality of micro channels are arranged in parallel. In other embodiments the plurality of micro channels have a rectangular cross section and the plurality of micro channels have a width and a depth, the ratio of width to depth being between 1:5 and 1:15.

Other aspects and features of the present invention will become apparent to those ordinarily skilled in the art upon review of the following description of specific embodiments of the invention in conjunction with the accompanying figures.

### BRIEF DESCRIPTION OF THE SEVERAL VIEWS OF THE DRAWING(S)

Embodiments of the present invention will now be described, by way of example only, with reference to the attached Figures, wherein:

FIG. 1 depicts a general example of a magnetron sputtering reactor;

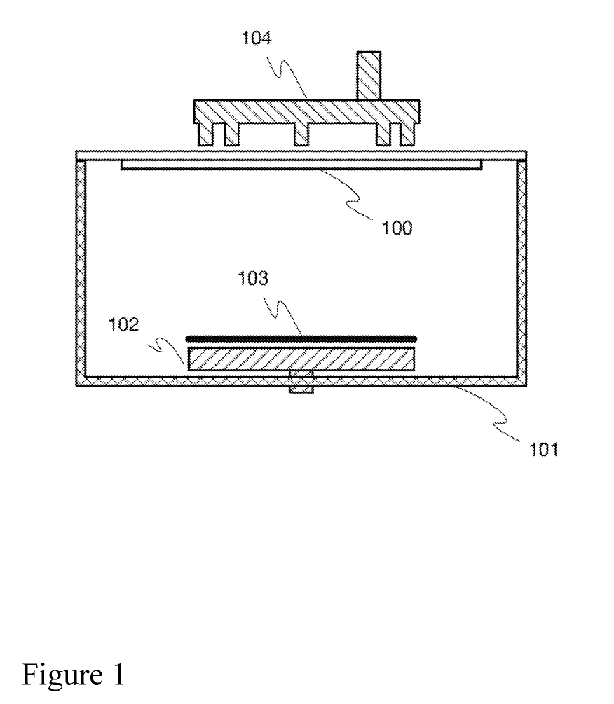

FIG. 2 depicts a view of the top, back plate of a sputtering target as well as a side view;

FIG. 3 depicts a side or cross section view of a sputtering target according to embodiments of the invention;

FIG. 4 depicts a close up of the micro channels with key parameters illustrated.

FIG. 5 depicts a variety of cross section shapes that the micro channels may have.

### DETAILED DESCRIPTION OF THE INVENTION

Embodiments of the invention are directed towards a sputtering target comprising a plurality of parallel micro channels inset in the exterior surface of the target's backing plate and the use of a nano fluid liquid as a coolant.

Embodiments of the invention comprise a sputtering target that implements a plurality of micro channels within the exterior surface of the backing plate, the heat transfer surface. The use of micro grooves or channels increase the heat transfer by increasing the surface area of the target's backing plate. The heat transfer is further improved by the micro channels that increase the number of surface corners and edges in the surface of the improved sputtering target. The micro channels provide straight paths that allow an uninterrupted flow of coolant across the heat transfer surface.

Embodiments of the invention may also make use of nano fluids as a coolant. Nano fluids, liquids that have particles suspended within, enhance the interaction properties of the coolant with the target backing plate and within the micro channels. The nano particles do not settle under gravity and do not block the flow of the coolant over the target.

Efficient heat transfer to cool the target involves both conduction and convection. Conduction heat transfer is dependent on three main factors. The first is the surface area where the heat transfer is taking place. The heat transfer will be higher for larger surface area. The second is the thermal conduction coefficient of the material. The heat transfer will be higher for materials with a large thermal conduction coefficient which is typically titanium but may also be aluminium or other materials. The third factor is the temperature difference between the high and low temperature sides. The heat transfer will be higher for larger temperature differences between high and low sides. In a sputtering reactor, the space between the sputtering target 100 and the magnetron 104 may be as small as 1.5 mm which limits the ability to use these factors efficiently in such a small volume of space. Embodiments of the invention increase the surface area of the exterior surface of the backing plate of the sputtering target 100 where cooling is taking place and passes the coolant along the coolant pathway as quickly so that the temperature difference over the surface of the plate can be maintained constant while maintaining as large a temperature difference between the target backing plate and the coolant as possible.

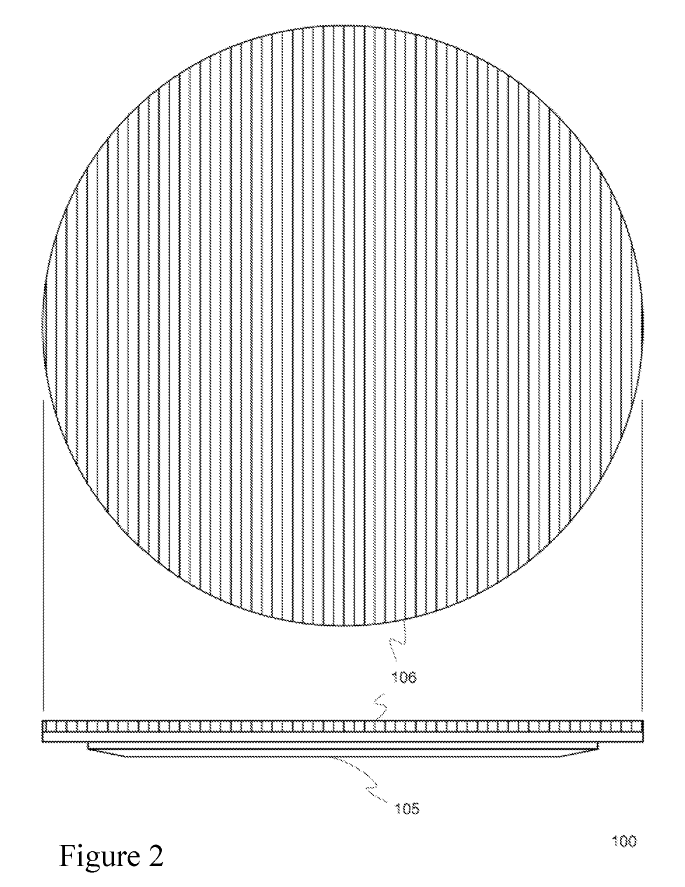

FIG. 2 illustrates an embodiment of the invention. A sputtering target 100 comprises an assembly of two components; a solid material target 105 made of or coated with the same material which is being deposited on the silicon wafer 103 and a target backing plate 106 used to fix the target material 105. These two parts are bonded together through a bonded diffusion process. When in use, the exterior surface of the backing plate 106 faces the magnetron 104. Cooling liquid is introduced between the magnetron 104 and the backing plate 106 to cool the target 100. The target backing plate is typically manufactured of titanium but may be manufactured of any suitable material such as aluminium as it is highly corrosion resistant, has good strength and has high thermal conductive properties.

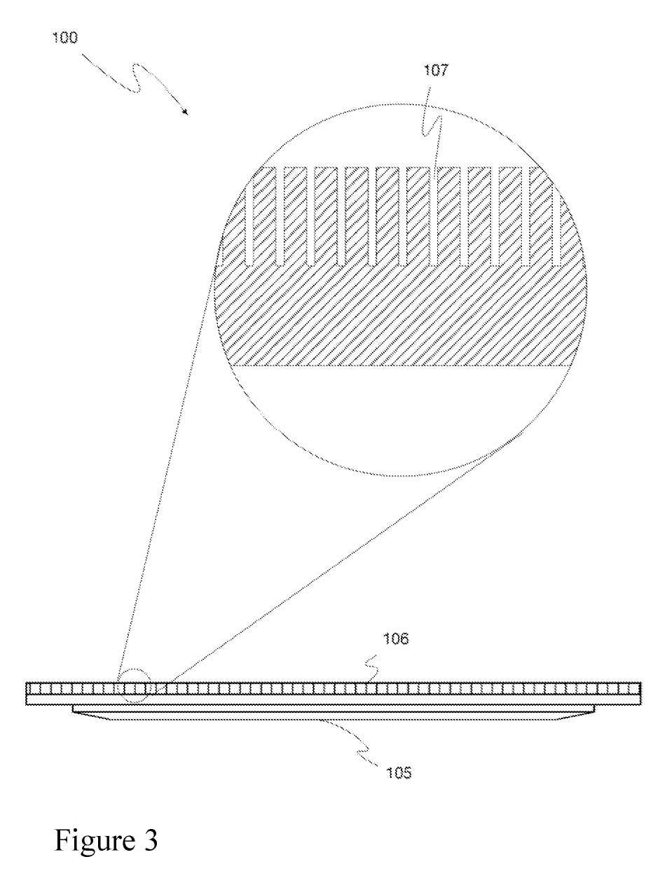

Referring to FIG. 3, the backing plate is manufactured, inset with a plurality of micro channels 107 arranged in a pattern, that span the surface of the backing plate of the target. The coolant flows through these channels 107 and it flows sufficiently fast to maintain a constant temperature difference between the coolant and the hot surface of the target 106. Preferably, the micro channels are arranged in a parallel layout as this offers good heat transfer and is relatively easy to manufacture. Alternatively, the micro channels 107 may be arranged radially around the centre of the target, starting from the centre and continuing to the edge of the target. Either the parallel or radial arrangement of micro channels may be used. However, the radial layout suffers from two drawbacks. The first is that the small micro channels are more difficult to manufacture as the they must all converge at the centre of the target where there is less surface area. Furthermore, the spacing between micro channels increases towards the outer edge of the target, decreasing the number of micro channels in the target backing plate and reducing the effective surface area that is used for heat transfer. Other layouts of micro channels may also be used, such as a spiral arrangement, but this layout is also likely to be difficult to manufacture without an accompanying benefit over the parallel micro channel layout.

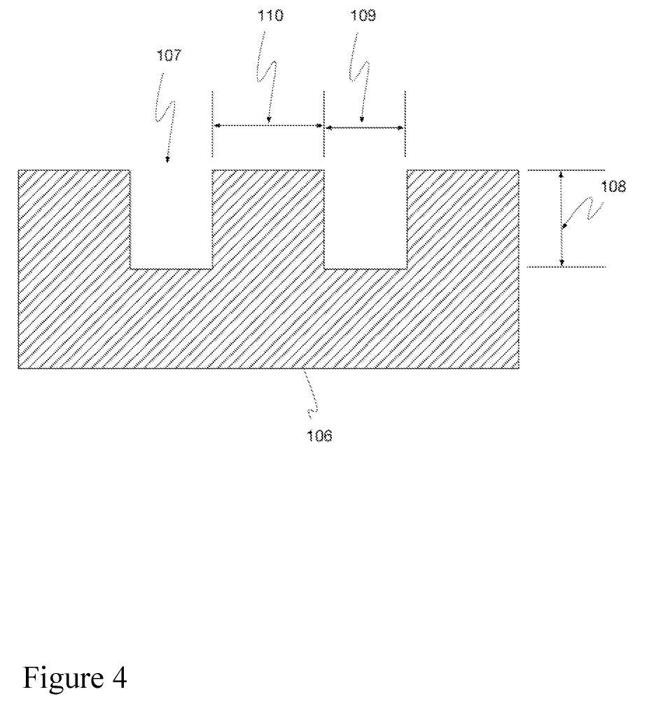

The use of micro channels in the exterior surface of the backing plate 106 increases the surface area. Referring to FIG. 4, the micro channels 107 are defined by their depth 108 and width 109. In order to increase the effective heat conduction surface, the number of micro channels should be large, the depth 108 should be large, and the width 109 should be small. A smaller width allows for the number of micro channels to be increased across the backing plate which increases the surface available for heat transfer. The value of height and width of the groove depends on the material of the target backing plate and the manufacturing capability and cost of the techniques available for forming the micro channels. For a 485 mm diameter backing plate surface area it is possible to manufacture approximately 240 micro channels with each channel having a 0.5 mm width 109. This channel width can be varied depending on the ability to manufacture the channel which is also dependent on the material of the target. With a 0.5 mm width 109, it is possible to form each channel to be 5 mm deep 108 in a titanium backing plate 106. The micro channels themselves may be manufactured using a number of techniques including cutting with a laser or using a circular shaped saw disk to mechanically cut the channels.

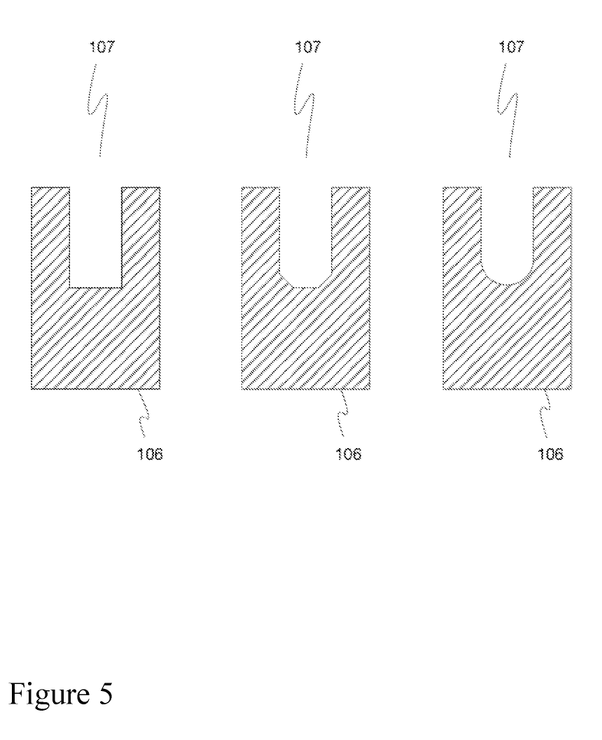

The cross section of the geometry also plays a major role in the efficiency of the micro channels 107. Referring to FIG. 5, there are several options of cross section shapes that may be chosen for the micro channels with examples of circular, triangular and rectangular being illustrated. Corners of the profile a major role in the heat transfer by mean of radiation, therefore micro channels 107 with a rectangular cross section will perform better than those with a triangular or circular cross section.

Embodiments of the invention may use nano fluids as a coolant. Conventional coolants are typically deionized water or coolants containing mm or μm-sized particles. However, these particles tend to clog tiny channels and settle in the liquid. Nano fluids are a new class of advanced heat transfer fluids that are engineered by dispersing nano particles smaller than 100 nm in mean diameter into conventional heat transfer fluids such as deionized water. Nano fluids have unique transport properties such as non-settlement of the particles under gravity and will not block the flow of coolant across the exterior surface of the backing plate 106. Along the flow path, these nano particles can also cause turbulent motions at the nano as well as micro level that can increase the convective heat transfer. The nano fluid used in embodiments of the invention will be circulated in a same manner as other known target cooling mechanisms. Embodiments of the invention may use aluminium oxide nano particles with 4% concentration in a base fluid of deionized water.

The ensuing description provides representative embodiment(s) only, and is not intended to limit the scope, applicability or configuration of the disclosure. Rather, the ensuing description of the embodiment(s) will provide those skilled in the art with an enabling description for implementing an embodiment or embodiments of the invention. It being understood that various changes can be made in the function and arrangement of elements without departing from the spirit and scope as set forth in the appended claims. Accordingly, an embodiment is an example or implementation of the inventions and not the sole implementation. Various appearances of “one embodiment,” “an embodiment” or “some embodiments” do not necessarily all refer to the same embodiments. Although various features of the invention may be described in the context of a single embodiment, the features may also be provided separately or in any suitable combination. Conversely, although the invention may be described herein in the context of separate embodiments for clarity, the invention can also be implemented in a single embodiment or any combination of embodiments.

Reference in the specification to “one embodiment”, “an embodiment”, “some embodiments” or “other embodiments” means that a particular feature, structure, or characteristic described in connection with the embodiments is included in at least one embodiment, but not necessarily all embodiments, of the inventions. The phraseology and terminology employed herein is not to be construed as limiting but is for descriptive purpose only. It is to be understood that where the claims or specification refer to “a” or “an” element, such reference is not to be construed as there being only one of that element. It is to be understood that where the specification states that a component feature, structure, or characteristic “may”, “might”, “can” or “could” be included, that particular component, feature, structure, or characteristic is not required to be included.

Reference to terms such as “left”, “right”, “top”, “bottom”, “front” and “back” are intended for use in respect to the orientation of the particular feature, structure, or element within the figures depicting embodiments of the invention. It would be evident that such directional terminology with respect to the actual use of a device has no specific meaning as the device can be employed in a multiplicity of orientations by the user or users.

Reference to terms “including”, “comprising”, “consisting” and grammatical variants thereof do not preclude the addition of one or more components, features, steps, integers or groups thereof and that the terms are not to be construed as specifying components, features, steps or integers. Likewise, the phrase “consisting essentially of”, and grammatical variants thereof, when used herein is not to be construed as excluding additional components, steps, features integers or groups thereof but rather that the additional features, integers, steps, components or groups thereof do not materially alter the basic and novel characteristics of the claimed composition, device or method. If the specification or claims refer to “an additional” element, that does not preclude there being more than one of the additional element.

1. A sputtering target comprising:
a target material, the target material being a circular disk and comprising a sputtering material; and
a backing plate bonded to the target material, the backing plate having a circular disk shape and comprising an external surface, the external surface comprising a plurality of micro channels inset within, the plurality of micro channels spanning the external surface.

2. The sputtering target of claim 1 wherein the plurality of micro channels are arranged in parallel.

3. The sputtering target of claim 1 wherein the plurality of micro channels extend radially from the centre of the external surface.

4. The sputtering target of claim 1 wherein the plurality of micro channels have a rectangular cross section.

5. The sputtering target of claim 4 wherein the plurality of micro channels have a width and a depth, the ratio of width to depth being between 1:5 and 1:15.

6. The sputtering target of claim 1 wherein the bottom portion of the plurality of micro channels have a circular cross section.

7. The sputtering target of claim 1 wherein the bottom portion of the plurality of micro channels have a triangular cross section.

8. A method of cooling a sputtering target, the method comprising:
arranging a sputtering target in a sputtering reactor, the sputtering target comprising a target material bonded to a backing plate, an external surface of the backing plate disposed external to the sputtering reactor and facing a magnetron; and
introducing a nano fluid onto the external surface between the magnetron and the sputtering target.

9. The method of claim 8 wherein the nano fluid comprises a plurality of particles smaller than 100 nm in mean diameter.

10. The method of claim 9 wherein the plurality of particles are comprised of aluminum oxide.

11. The method of claim 9 wherein the plurality of particles comprise between 3% and 5% concentration of the nano fluid.

12. The method of claim 8 wherein the external surface comprises a plurality of micro channels inset within, the plurality of micro channels spanning the external surface.

13. The method of claim 12 wherein the plurality of micro channels are arranged in parallel.

14. The method of claim 13 wherein the plurality of micro channels have a rectangular cross section.

15. The method of claim 12 wherein the plurality of micro channels have a width and a depth, the ratio of width to depth being between 1:5 and 1:15.
